(19) United States
(12) Patent Application Publication
(10) Pub. No.: US 2008/0132076 A1
(43) Pub. Date: Jun. 5, 2008

(54) METHOD FOR AVOIDING POLYSILICON DEFECT

(75) Inventors: Yun Yang, Shanghai (CN); Zhenliang Yang, Shanghai (CN); Hyun Jae Kim, Shanghai (CN); Gangning Wang, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: Semiconductor Manufacturing International ( Shanghai) Corporation, Shanghai (CN)

(21) Appl. No.: 11/852,936

(22) Filed: Sep. 10, 2007

(30) Foreign Application Priority Data
Dec. 4, 2006 (CN) 200610119058.3

(51) Int. Cl. H01L 21/311

(52) U.S. Cl. 438/703; 257/E21.249

(57) ABSTRACT

A method for avoiding a polysilicon defect includes: forming a silicon oxide layer on a silicon substrate; forming a polysilicon plug in the silicon oxide layer, with the polysilicon plug going through the silicon oxide layer; forming on the silicon oxide layer a silicon nitride layer covering the polysilicon plug; forming interlayer dielectric layers on the silicon nitride layer; etching the interlayer dielectric layers over the polysilicon plug to form an opening; etching the silicon nitride layer at the opening to expose the polysilicon plug; and filling polysilicon into the opening such that the opening is in communication with polysilicon plug. In this way, there will be no reaction of the HSC1 with the polysilicon plug due to the protection by the silicon nitride layer. Moreover, since the silicon nitride layer is the last to be etched, there will be no residual thereof, enabling a subsequent flat filling.

### CROSS-REFERENCE TO RELATED APPLICATIONS

This application is claiming priority of Chinese Application No. 200610119058.3 filed Dec. 4, 2006, entitled “Method for Avoiding Polysilicon Defect” which application is incorporated by reference herein in its entirety.

### FIELD OF THE INVENTION

The present invention relates to a method for fabricating a semiconductor memory device, and more particularly to a method for avoiding a polysilicon defect.

### BACKGROUND OF THE INVENTION

The dynamic random access memory as a widely used integrated circuit device is typically consisted of a transistor and a capacitor. The capacitor is used for storing charges to provide electric information, and hence shall have a sufficiently large capacitance so as to prevent loss of data and to lower the frequency of refreshing.

As the integration level of semiconductor devices in integrated circuit fabricating process increases continuously, the density of storage cells of the dynamic random access memory tends to be increasingly large, and thus, the area of a storage cell of the dynamic random access memory available for the capacitor tends to be increasingly small. In order to maintain a reliable performance while the area for the capacitor reduces, it is important to maintain the capacitance of each capacitor while the area occupied by the capacitor reduces. To increase the capacitance of the capacitor, it may be achieved in theory by: (1) increasing the surface area of a storage electrode; (2) increasing the dielectric constant of a dielectric layer; and (3) reducing the thickness of the dielectric layer. Recently, a three-dimension structure for the capacitor has been also developed to increase the capacitance of the storage cell, for instance, a dual-stack structure, a fin structure, a disperse-stack structure, a crown structure, etc. In the case that a polysilicon storage node is used, the capacitance can also be increased by forming a hemispherical grain (HSG) polysilicon layer on the polysilicon layer.

The US patent application US2006197131 discloses a method for forming a polysilicon layer during a process of fabricating a capacitor of a dynamic random access memory. As illustrated in FIG. 1A, a field effect transistor of a dynamic random access memory is formed on a silicon substrate 100. The field effect transistor includes a gate 104, a drain 105 and a source 106. A cap layer 103 is formed on the gate 104, and a gap wall 107 is formed on each sidewall of the gate 104. The cap layer 103 and the gap wall 107 are made of silicon nitride. Then, a silicon oxide layer 108 is formed on the silicon substrate 100 using a Chemical Vapor Deposition (CVD) process, and a silicon nitride layer 110 is formed on the silicon oxide layer 108 using a chemical vapor deposition process.

As illustrated in FIG. 1B, a first photoresist layer (not shown) is formed on the silicon nitride layer 110 using a spin coating process, and an opening pattern corresponding to the source 106 is formed on the first photoresist layer after exposure and development processes; the silicon nitride layer 110 and the silicon oxide layer 108 are etched using the first photoresist layer as a mask until the silicon substrate 100 is exposed; a contact window opening 112 is formed at the source 106; the first photoresist layer 111 is removed; and a polysilicon layer 114 is formed on the silicon nitride layer 110 using a chemical vapor deposition process, and fills up the contact window opening 112.

As illustrated in FIG. 1C, the polysilicon layer 114 is ground using a chemical mechanical polishing process until the silicon nitride layer 110 is exposed; a polysilicon plug 115 is formed in the contact window opening 112; a first interlayer dielectric layer 116 made of borophosphosilicate glass (BPSG) is formed on the silicon nitride layer 110 using a chemical vapor deposition process; and a second interlayer dielectric layer 118 made of tetraethyl orthosilicate (TEOS) is formed on the first interlayer dielectric layer 116 using a chemical vapor deposition process.

As illustrated in FIG. 1D, a patterned second photoresist layer (not shown) is formed on the tetraethyl orthosilicate layer 118 using a spin coating process; the second interlayer dielectric layer 118, the first interlayer dielectric layer 116 and the silicon nitride layer 110 are etched using a dry etching process with the second photoresist layer as a mask until the silicon oxide layer 108 is exposed, thus forming an opening 119 in communication with the polysilicon plug 115. Since the dry etching has different etching rates for BPSG and TEOS, respectively 5000 Å/min for BPSG and 7000 Å/min for TEOS, an opening width h₂ of the second interlayer dielectric layer 118 is larger than an opening width h₁ of the first interlayer dielectric layer 116 by 200 Å after the etching.

As illustrated in FIG. 1E, in order to make the opening width of the first interlayer dielectric layer 116 and that of the second interlayer dielectric layer 118 consistent with each other, hot standard cleaning solution No. 1 (HSC1) with an etching selectivity 1:10 of TEOS to BPSG is used to further etch the second interlayer dielectric layer 118 and the first interlayer dielectric layer 116; buffer oxide etchant (BOE) with an etching selectivity 1:1 of TEOS to BPSG is used to further etch the second interlayer dielectric layer 118 and the first interlayer dielectric layer 116, so as to increase the width of the opening 119, for example, by 30 Å to 50 Å, hence increasing the surface area of the storage electrode and thus improving the capacitance of the capacitor; and the second photoresist layer is removed, the opening 119 is filled up with polysilicon, with an HSG polysilicon layer formed on the polysilicon.

FIG. 2A illustrates the formed opening 119 as observed by an electron microscope with a magnification of 150,000. When the width of the opening 119 is increased, the silicon nitride layer (as shown with ellipses in the figure) is not removed at the opening 119 because the HSC1 and the BOE can not the etch silicon nitride, which may result in unevenness upon subsequent filling of polysilicon.

FIG. 2B illustrates the formed opening 119 as observed by an electron microscope with a magnification of 250,000. Since the HSC1 may react with the polysilicon plug when etching the second interlayer dielectric layer 118 and the first interlay dielectric layer 116, a defect (as shown with an ellipse in the figure) may occur in the polysilicon plug, resulting in an electric failure.

The first interlayer dielectric layer is made of BPSG, and the second interlayer dielectric layer is made of TEOS; the dry etching gas has different etching rates for TEOS and BPSG; consequently, the opening width of the first interlayer dielectric layer and that of the second interlayer dielectric layer are different. Therefore, the HSC1 is required to etch the opening width of the first interlayer dielectric layer and that of the second interlayer dielectric layer to be equal to each other. However, the HSC1 may react with the polysilicon plug, and a defect may occur in the polysilicon plug, resulting in an electric failure. Furthermore, when the HSC1 and the BOE are used to etch the interlayer dielectric layers, there may be a residual of the silicon nitride layer due to the fact that HSC1 and the BOE are unable to etch the silicon nitride layer, and thus a cavity or unevenness may occur during subsequent filling of a thin film.

### SUMMARY OF THE INVENTION

The invention tends to provide a method for avoiding a polysilicon defect. This method can prevent a defect from occurring in a polysilicon plug, which defect may result in an electric failure, and can prevent a residual of a silicon nitride layer from occurring during etching, which residual may result in a cavity or unevenness occurring during subsequent filling of polysilicon.

To this end, an embodiment of the invention provides a method for avoiding a polysilicon defect. The method includes:

forming a silicon oxide layer on a silicon substrate;

forming a polysilicon plug in the silicon oxide layer, with the polysilicon plug going through the silicon oxide layer;

forming on the silicon oxide layer a silicon nitride layer covering the polysilicon plug;

forming interlayer dielectric layers on the silicon nitride layer;

etching the interlayer dielectric layers over the polysilicon plug to form an opening;

etching the silicon nitride layer at the opening to expose the polysilicon plug; and

filling polysilicon into the opening such that the opening is in communication with polysilicon plug.

Preferably, the silicon nitride layer may be formed using a chemical vapor deposition process. Preferably, the silicon nitride layer may have a thickness ranging from 400 \acute{Å} to 800 \acute{Å}. Preferably, the silicon nitride layer may be etched using a dry etching process. Preferably, gases of CHF₃ and O₂ may be used for the dry etching process, and a ratio of CHF₃ to O₂ may be 15:5.

Preferably, the step of forming interlayer dielectric layers on the silicon nitride layer may include: forming a first interlayer dielectric layer on the silicon nitride layer; and forming a second interlayer dielectric layer on the first interlayer dielectric layer.

Preferably, the first interlayer dielectric layer and the second interlayer dielectric layer may be formed using a chemical vapor deposition process. Preferably, the first interlayer dielectric layer may be made of borophosphosilicate glass. Preferably, the second interlayer dielectric layer may be made of tetraethyl orthosilicate.

Preferably, the process of etching the interlayer dielectric layers over the polysilicon plug to form an opening may include: performing a first etching on the first interlayer dielectric layer and the second interlayer dielectric layer over the polysilicon plug by a dry etching process, to form the opening corresponding to the polysilicon plug; performing a second etching on the first interlayer dielectric layer and the second interlayer dielectric layer by a wet etching process, to make an opening width of the first interlayer dielectric layer and an opening width of the second interlayer dielectric layer consistent with each other; and performing a third etching on the first interlayer dielectric layer and the second interlayer dielectric layer by a wet etching process, to make the opening widths larger.

Preferably, gases of C₄F₆ and O₂ may be used for the first etching.

Preferably, a solution of hot standard cleaning solution No. 1 may be used for the second etching.

Preferably, a solution of buffer oxide etchant may be used for the third etching.

The embodiments of the invention are advantageous over the prior art in the following. The silicon nitride layer is formed after the polysilicon plug is fabricated, and during the subsequent etching, there will no reaction of the HSC1 with the polysilicon plug due to the protection by the silicon nitride layer. Therefore, no defect will occur in the polysilicon plug, and thus the electric performance can be improved. Moreover, since the silicon nitride layer is the last to be etched, there will be no residual thereof, enabling a subsequent flat filling of a thin film.

### BRIEF DESCRIPTION OF THE DRAWINGS

FIG. 1A to FIG. 1E are schematic diagrams of forming a polysilicon layer during fabricating a capacitor of a dynamic random access memory in the prior art.

FIG. 2A and FIG. 2B are schematic diagrams of a defect in the polysilicon layer of the capacitor of the dynamic random access memory fabricated in the prior art as observed with an electron microscope.

FIG. 3 is a flow chart of avoiding a defect in a polysilicon layer according to an embodiment of the invention.

FIG. 4A to FIG. 4F are schematic diagrams of forming a polysilicon layer during fabricating a capacitor of a dynamic random access memory according to an embodiment of the invention.

FIG. 5 is a schematic diagram of a polysilicon layer of the capacitor of the dynamic random access memory fabricated according to an embodiment of the invention as observed with an electron microscope.

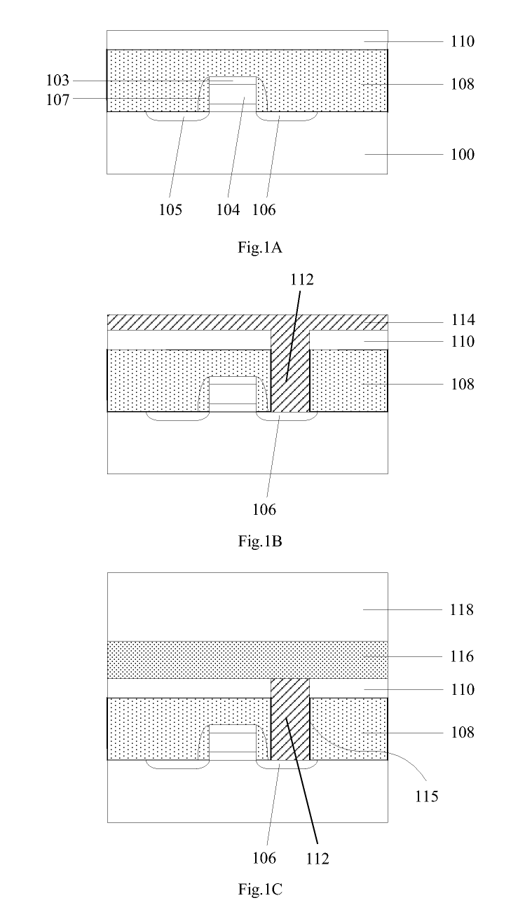

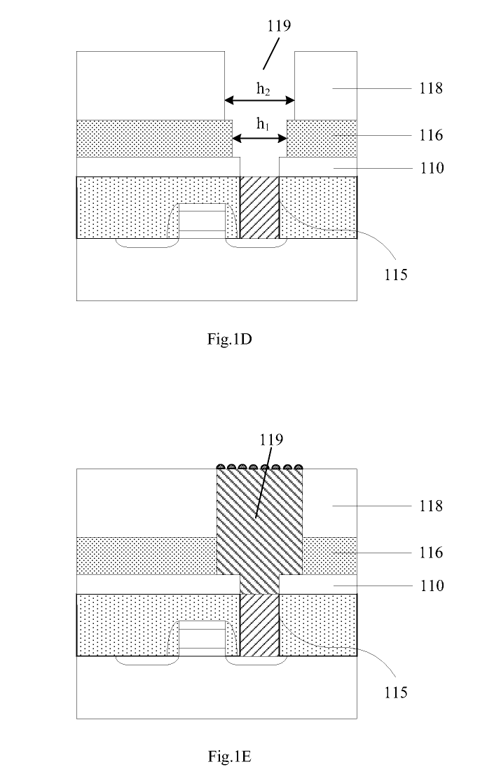

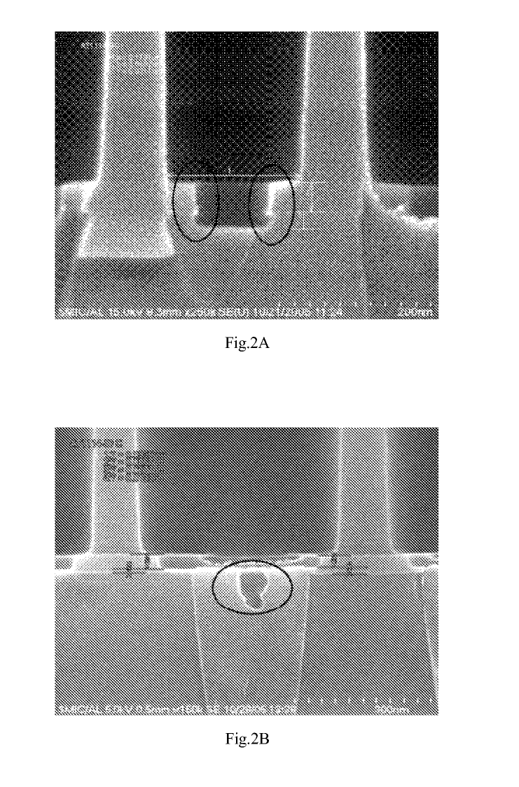

### DETAILED DESCRIPTION OF THE EMBODIMENTS

In the formation of a polysilicon layer during the fabrication of a capacitor in a dynamic random access memory in the prior art, the first interlayer dielectric layer is made of TEOS, and the second interlayer dielectric layer is made of BPSG; the dry etching gas has different etching rates for TEOS and BPSG; consequently, the opening width of the first interlayer dielectric layer and that of the second interlayer dielectric layer are different. Therefore, the HSC1 is required to etch the opening width of the first interlayer dielectric layer and that of the second interlayer dielectric layer to be equal to each other. However, the HSC1 may react with the polysilicon plug, and a defect may occur in the polysilicon plug, resulting in an electric failure. Furthermore, when the HSC1 and the BOE are used to etch the interlayer dielectric layers, there may be a residual of the silicon nitride layer due to the fact that HSC1 and the BOE are unable to etch the silicon nitride layer, and thus a cavity or unevenness may occur during subsequent filling of a thin film. According to an embodiment of the invention, a silicon nitride layer is formed after a polysilicon plug is fabricated. During subsequent etching, there will be no reaction of the HSC1 with the polysilicon plug due to the protection by the silicon nitride layer. Therefore, no defect will occur in the polysilicon plug, and thus the electric performance can be improved. Moreover, since the silicon nitride layer is the last to be etched, there will be no residual thereof, enabling a subsequent flat filling of a thin film. In order to make the above objects, features and advantages of the invention more apparent and readily understood, embodiments of the invention will be described in details with reference to the accompanying drawings.

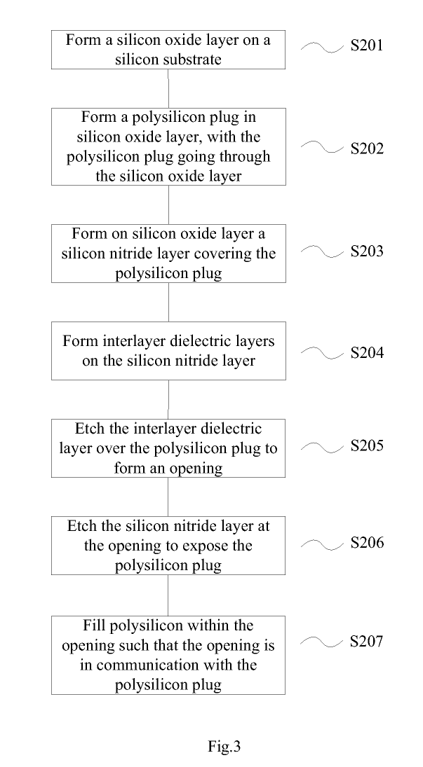

FIG. 3 is a flow chart of avoiding a defect in a polysilicon layer. As illustrated in FIG. 3, a silicon oxide layer is formed on a silicon substrate in step S201; a polysilicon plug is formed in the silicon oxide layer in step S202, which polysilicon plug goes through the silicon oxide layer; a silicon nitride layer is formed on the silicon oxide layer to cover the polysilicon plug in step S203; interlayer dielectric layers are formed on the silicon nitride layer in step S204; the interlayer dielectric layers over the polysilicon plug are etched, thus forming an opening, in step S205; the silicon nitride layer at the opening is etched, exposing the polysilicon plug, in step S206; and polysilicon is filled within the opening such that the opening is in communication with the polysilicon plug, in step S207.

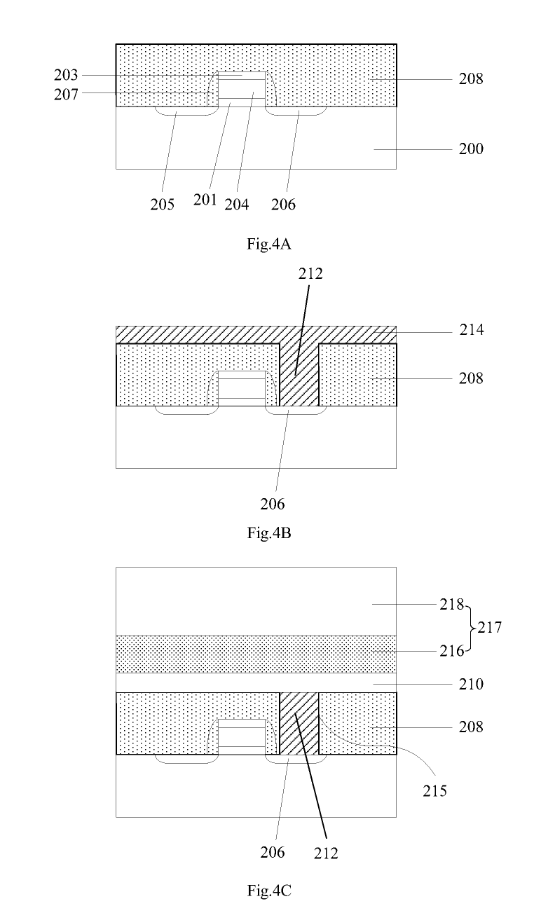

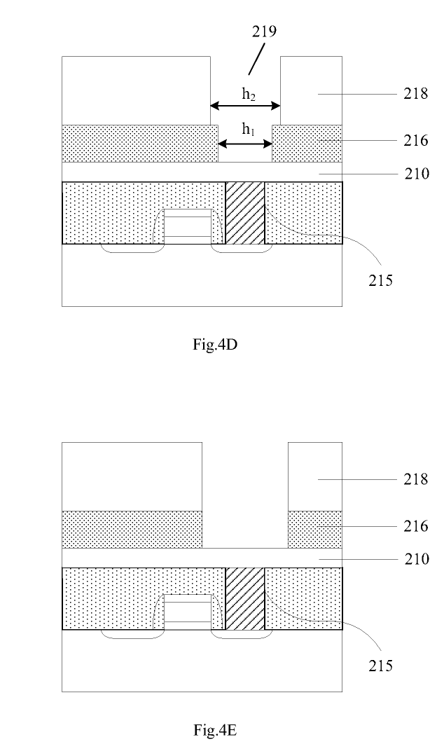

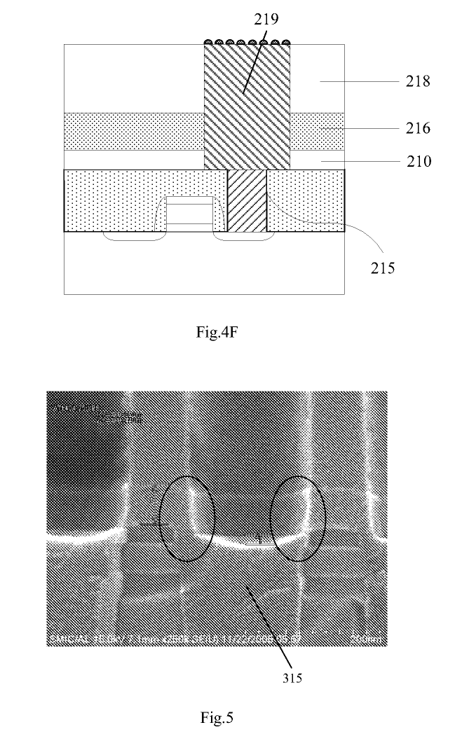

FIG. 4A to FIG. 4F are schematic diagrams of forming a polysilicon layer during fabricating a capacitor of a dynamic random access memory according to an embodiment of the invention. As illustrated in FIG. 4A, a field effect transistor of a dynamic random access memory is formed on a silicon substrate 200. The field effect transistor includes a gate 204, a drain 205 and a source 206. A cap layer 203 is formed on the gate 204, and a gap wall 207 is formed on each side of the gate 204. The cap layer 203 and the gap wall 207 are made of silicon nitride. Then, a silicon oxide layer 208 for isolation between devices is formed on the silicon substrate 200 using a CVD process.

Technologies for fabricating a field effect transistor are well known in the art. Ions are implanted into the silicon substrate 200, thus forming a well; the silicon substrate 200 is oxidized through providing oxygen in a furnace, thus forming a gate oxide layer 201; a polysilicon layer is formed on the gate oxide layer 201 as the gate 204 using a CVD process; the cap layer 203 is formed on the polysilicon layer using a low-pressure CVD process, for facilitating a subsequent formation of a self-aligned bit line contact hole; the gate oxide layer 201, the gate 204 and the cap layer 204 constitute a gate structure; ions are implanted into the silicon substrate 200 at both sides of the gate structure using the gate structure as a mask, thus forming a lightly doped drain; the gap side 207 is formed at each side of the gate structure; and ions are implanted into the silicon substrate 200 at both sides of the gate structure using the gate structure as a mask, performing heavy doping and thus forming the drain 205 and the drain 206.

As illustrated in FIG. 4B, a first photoresist layer (not shown) is formed on the silicon oxide layer 208 using a spin coating process, and an opening pattern corresponding to the source 206 is formed on the first photoresist by exposure and development processes; the silicon oxide layer 208 is etched along the opening pattern using the first photoresist layer as a mask until the silicon substrate 200 is exposed, thus forming a contact window opening 212 at the source 206; the first photoresist layer is removed using ashing and wet etching processes; and a polysilicon layer 214 is formed on the silicon oxide layer 208 using a CVD process, and fills up the contact window opening 212.

Technologies for removing the first photoresist layer are well known in the art. The first photoresist layer is ashed at a temperature of 100° C. to 300° C.; since the first photoresist layer can not be removed completely through ashing, a residual of the first photoresist layer is removed through a wet etching process.

As illustrated in FIG. 4C, the polysilicon layer 214 is ground by a CMP process until the silicon oxide layer 208 is exposed, thus forming a polysilicon plug 215 at the contact window opening 212; a silicon nitride layer 210 of 400 \acute{Å} to 800 \acute{Å}, which functions as a stop layer during subsequent etching of the interlayer dielectric layers, is formed on the silicon oxide layer 208 using a CVD process; and interlayer dielectric layers 217, including a first interlayer dielectric layer 216 made of BPSG with a thickness ranging from 12000 \acute{Å} to 15000 \acute{Å}, and a second interlayer dielectric layer 218 made of TEOS with a thickness ranging from 500 \acute{Å} to 8000 \acute{Å}, are formed on the silicon nitride layer 210 using a CVD process.

In this embodiment, the silicon nitride layer 210 has a thickness of for example, 400 \acute{Å}, 500 \acute{Å}, 600 \acute{Å}, 700 \acute{Å} or 800 \acute{Å}.

In this embodiment, the first interlayer dielectric layer 216 has a thickness of, for example, 12000 \acute{Å}, 13000 \acute{Å}, 14000 \acute{Å} or 15000 \acute{Å}; the second interlayer dielectric layer 218 has a thickness of, for example, 5000 \acute{Å}, 6000 \acute{Å}, 7000 \acute{Å} or 8000 \acute{Å}.

As illustrated in FIG. 4D, a second patterned photoresist layer (not shown) is formed on the second interlayer dielectric layer 218 using a spin coating process; the first interlayer dielectric layer 216 and the second interlayer dielectric layer 218 are etched using a dry etching process with the second photoresist layer as a mask until the silicon nitride layer 210 is exposed, thus forming an opening 219 corresponding to the polysilicon plug 215. Since gases of C₄F₆ and O₂ are used in the dry etching process and they have different etching rates for TEOS and BPSG, respectively 50000 \acute{Å}/min for BPSG and 7000 \acute{Å}/min for TEOS, an opening width h₂ of the second interlayer dielectric layer 218 is larger than an opening width h₁ of the first interlayer dielectric layer 216 by 200 \acute{Å}.

In this embodiment, a ratio of the gases C₄F₆ and O₂ used in the dry etching process for etching the first interlayer dielectric layer 216 and the second interlayer dielectric layer 218 is 30:24.

As illustrated in FIG. 4E, in order to make the opening width of the first interlayer dielectric layer 216 and the opening width of the second interlayer dielectric layer 218 consistent with each other, hot standard cleaning solution No. 1 (HSC1) with an etching selectivity 1:10 of TEOS to BPSG is used to wet-etch the second interlayer dielectric layer 218 and the first interlayer dielectric layer 216, so that the opening width of the first interlayer dielectric layer 216 and that of the second interlayer dielectric layer 218 is consistent with each other; buffer oxide etchant (BOE) with an etching selectivity 1:1 of TEOS to BPSG is used to etch the second interlayer dielectric layer 218 and the first interlayer dielectric layer 216, so as to increase the width of the opening 219 by 30 Å to 50 Å, hence increasing the surface area of a storage electrode and thus improving the capacitance of the capacitor.

In this embodiment, the second interlayer dielectric layer 218 and the first interlayer dielectric layer 216 are wet-etched with the HSC1 for a period of time ranging from 150 seconds to 250 seconds, for example, 150 seconds, 170 seconds, 190 seconds, 210 seconds, 230 seconds or 250 seconds.

In this embodiment, the second interlayer dielectric layer 218 and the first interlayer dielectric layer 216 are wet-etched with the BOE for a period of time ranging from 10 seconds to 50 seconds, for example, 10 seconds, 20 seconds, 30 seconds, 40 seconds or 50 seconds.

As illustrated FIG. 4F, the silicon nitride layer 210 is etched using a dry etching process, thus exposing the polysilicon plug 215; the second photoresist layer is removed using ashing and wet etching processes; polysilicon is filled up within the opening 210, such that the opening is in communication with the polysilicon plug 215; and an HSG polysilicon layer is formed on the polysilicon, which HSG polysilicon layer can also increase the capacitance.

Technologies for removing the second photoresist layer are well known in the art. The second photoresist layer is ashed at a temperature of 100° C. to 300° C.; since the second photoresist layer can not be removed completely through ashing, a residual of the second photoresist layer is removed through a wet etching process.

In this embodiment, gases of CHF₃ and O₂ are used in the dry etching process to etch the silicon nitride layer 210, and a ratio of CHF₃ to O₂ is 15:5.

FIG. 5 is a schematic diagram of a polysilicon layer of the capacitor of the dynamic random access memory fabricated according to an embodiment of the invention as observed with an electron microscope. As illustrated in FIG. 5, when the profile of capacitor of the dynamic random access memory is observed by an electron microscope with a magnification of 250,000, no defect can be observed on the polysilicon plug 315. This is because that the silicon nitride layer is formed after the formation of the polysilicon plug, and thus when etching the interlayer dielectric layers with the HSC1, the HSC1 will not react with the polysilicon plug due to the protection to the polysilicon plug by the silicon nitride layer. Moreover, the silicon nitride layer is etched after the formation of the opening, so the silicon nitride layer at the opening can be removed completely, without residual of the silicon nitride occurring; therefore, no unevenness will occur during subsequent filling of polysilicon.

Although the present invention has been disclosed with the preferred embodiments, it is apparent that those embodiments are not restrictive. Various modifications and variations can be made on the present invention by those skilled in the art without departing from the spirit and scope of the present invention as defined by the accompanying claims.

What is claimed is:

1. A method for avoiding a polysilicon defect, comprising:
forming a silicon oxide layer on a silicon substrate;
forming a polysilicon plug in the silicon oxide layer, with the polysilicon plug going through the silicon oxide layer;
forming on the silicon oxide layer a silicon nitride layer covering the polysilicon plug;
forming interlayer dielectric layers on the silicon nitride layer;
etching the interlayer dielectric layers over the polysilicon plug to form an opening;
etching the silicon nitride layer at the opening to expose the polysilicon plug; and
filling polysilicon into the opening such that the opening is in communication with polysilicon plug.

2. The method according to claim 1, wherein the silicon nitride layer is formed using a chemical vapor deposition process.

3. The method according to claim 2, wherein the silicon nitride layer has a thickness ranging from 400 \acute{Å}, to 800 \acute{Å}.

4. The method according to claim 3, wherein the silicon nitride layer is etched using a dry etching process.

5. The method according to claim 4, wherein gases of CHF₃ and O₂ are used in the dry etching process, and a ratio of CHF₃ to O₂ is 15:5.

6. The method according to claim 1, wherein the step of forming interlayer dielectric layers on the silicon nitride layer comprises:
forming a first interlayer dielectric layer on the silicon nitride layer; and
forming a second interlayer dielectric layer on the first interlayer dielectric layer.

7. The method according to claim 6, wherein the first interlayer dielectric layer and the second interlayer dielectric layer are formed using a chemical vapor deposition process.

8. The method according to claim 7, wherein the first interlayer dielectric layer is made of borophosphosilicate glass.

9. The method according to claim 8, wherein the second interlayer dielectric layer is made of tetraethyl orthosilicate.

10. The method according to claim 6, wherein the process of etching the interlayer dielectric layers over the polysilicon plug to form an opening comprises:
performing a first etching on the first interlayer dielectric layer and the second interlayer dielectric layer over the polysilicon plug by a dry etching process, to form the opening corresponding to the polysilicon plug;
performing a second etching on the first interlayer dielectric layer and the second interlayer dielectric layer by a wet etching process, to make an opening width of the first interlayer dielectric layer and an opening width of the second interlayer dielectric layer consistent with each other; and
performing a third etching on the first interlayer dielectric layer and the second interlayer dielectric layer by a wet etching process, to make the opening widths larger.

11. The method according to claim 10, wherein gases of C₄F₆ and O₂ are used for the first etching.

12. The method according to claim 10, wherein a solution of hot standard cleaning solution No. 1 is used for the second etching.

13. The method according to claim 10, wherein a solution of buffer oxide etchant is used for the third etching.
